(19) United States
(12) Patent Application Publication
(10) Pub. No.: US 2012/0192789 A1
(43) Pub. Date: Aug. 2, 2012

(54) DEPOSITION SYSTEMS AND PROCESSES

(75) Inventors: Karl-Josef Kramer, San Jose, CA (US); Mehrdad M. Moslehi, Los Altos, CA (US); Seiichi Yokoi, San Carlos, CA (US); George D. Kamian, Scotts Valley, CA (US); Shashank Sharma, San Jose, CA (US); Jay Ashjaee, Cupertino, CA (US)

(73) Assignee: SOLEXEL, INC., Milpitas, CA (US)

(21) Appl. No.: 13/341,965

(22) Filed: Dec. 31, 2011

Related U.S. Application Data
(63) Continuation-in-part of application No. 12/759,820, filed on Apr. 14, 2010.
(60) Provisional application No. 61/429,032, filed on Dec. 31, 2010.

(51) Int. Cl. C23C 16/455; C23C 16/458; C23C 16/52

(52) U.S. Cl. 118/712; 118/715; 118/728

(57) ABSTRACT

This disclosure enables gas recovery and utilization for use in deposition systems and processes. The system includes a thin-film semiconductor layer deposition system comprising a deposition reactor, precursor gas feeds, and a gas recovery system.

### CROSS-REFERENCE TO RELATED APPLICATIONS

This application claims priority to U.S. Provisional Patent Application Ser. No. 61/429,032 filed Dec. 31, 2010, which is hereby incorporated by reference in its entirety.

This application is also a continuation-in-part of U.S. patent application Ser. No. 12/759,820 (published as U.S. Pub. No. 2010/0267245), filed Apr. 14, 2010, which is hereby incorporated by reference in its entirety.

### FIELD

The present disclosure relates to epitaxial deposition. More particularly, the present disclosure relates to epitaxial deposition of silicon or other semiconducting materials.

### BACKGROUND

Currently, crystalline silicon (including multi- and mono-crystalline silicon) is the most dominant absorber material for commercial mass-produced photovoltaic (PV) applications. The relatively high efficiencies associated with mass-produced crystalline silicon solar cells and modules combined in conjunction with the abundance of material, well-established materials and manufacturing equipment supply chain, as well as the environmentally benign and nontoxic properties of silicon garner appeal for continued use and advancement. But the relatively high cost of high-purity crystalline silicon material itself limits the widespread use of these solar photovoltaic modules to enable grid parity compared to the mainstream fossil fuel sources of electricity generation.

At present, the cost of “wafering”, or producing pure polysilicon, crystallizing silicon (formation of monocrystalline ingots or cast Multicrystalline bricks) and cutting a wafer, accounts for about 40% to 60% of the finished solar module manufacturing cost. If a more direct way of making wafers were possible (as well as reducing the amount of silicon consumed in each wafer), great headway could be made in lowering the cost of solar cells and modules to enable grid parity.

There are different known methods of growing monocrystalline silicon and releasing or transferring the grown wafer. Regardless of the methods, a low cost epitaxial silicon deposition process accompanied by a high-volume, production-worthy, low cost method of forming a release layer are prerequisites for wider use of silicon solar cells. Another pre-requisite is the availability of a re-usable template or mold to repeatedly perform the sequence of sacrificial release layer formation, thin film (or thin foil) deposition, on-template processing, thin film layer release, as well as recovery/reconditioning of template.

Silicon epitaxial (epi) deposition (also called silicon epitaxy) was originally developed for the semiconductor industry. The requirements for the semiconductor industry, in both film properties and cost, are nearly polar opposites of requirements in the solar field. For example, semiconductor epi films are typically less than 5 μm (1 μm=10⁻⁶ meter) thick, while solar requires 10-80 μm of silicon. In order to achieve economies in the solar industry, the silicon cost per watt must reside in the <$0.25/watt or approximately <$1.00/wafer (assuming a 4 watt cell for 156 mm×156 mm cells).

The preferred low-cost precursor chemistry for epi is predominantly trichlorosilane (TCS), although for thinner films dichlorosilane (DCS: SiH₂Cl₂) or silane (SiH₄) may also be used. Epitaxial deposition for each chemical poses unique requirements and challenges in both equipment architecture and process conditions. Based on low cost and abundance, TCS is the chemistry of choice for the solar industry. The present invention will generally be described with regard to TCS, but one of ordinary skill in the art will recognize its applications to silane and other precursor chemicals (including but not limited to DCS and silicon tetra-chloride).

The microelectronics industry achieves economy of scale through obtaining greater yield by increasing the number of die (or chips) per wafer, scaling the wafer size, and enhancing the chip functionality (or integration density) with each successive new product generation. In the solar industry, economy is achieved through the industrialization of solar cell and module manufacturing processes with low cost high productivity equipment. Further economies of scale and mass market penetration are achieved through price reduction in raw materials through reduction of materials used per watt output of solar cells.

In order to achieve the necessary economy of scale for solar photovoltaics, process cost modeling is studied to identify and optimize equipment performance. Three categories of cost make up the total cost picture: Fixed Cost (FC), Recurring Cost (RC) and Yield Cost (YC). FC is made up of items such as equipment purchase price, installation cost and robotics or automation cost. RC is largely made up of electricity, gases, chemicals, operator salaries and maintenance technician support. YC may be interpreted as the total value of parts lost during production.

To achieve the lowest Cost of Ownership (CoO) numbers required by the solar field, all aspects of the cost picture must be optimized. The qualities of a low cost process are (in order of priority): 1) High equipment productivity, 2) High production yield, 3) Low RC, and 4) Low FC.

Designing highly productive and economical methods and process equipment requires a good understanding of the process requirements and reflecting those requirements into the equipment architecture. High yield requires a robust process and reliable equipment and as equipment productivity increases, so too does yield cost. Thus, a highly productive, reliable, and efficient reactor is essential for the high-throughput production of low-cost, high-efficiency solar cells. Low RC is also a prerequisite for overall low CoO. RC can impact plant site selection based on, for example, cost of local power or availability of bulk chemicals. FC, although important, is diluted by equipment productivity.

In summary, a high productivity, reliable, efficient manufacturing process flow and equipment is a prerequisite for low cost solar cells and modules.

A large contributor to reducing cost is the reduction in the net raw materials used in the production of the solar cells. For standard crystalline silicon, kerf loss during substrate slicing is such an issue where silicon is lost during the wire saw process. As the thickness of solar wafers has been reduced over the years (to now an average of 150 to 200 μm thick wafers), the relative amount of kerf loss compared to the silicon wafer thickness is quite significant.

If a deposition process is used instead for generating a thin film substrate—which later is processed further to generate a solar cell—on a template, then the overall gas utilization for the deposition process is a critical quantity.

Importantly, with the deposition gas being a very significant contributor to overall process cost, increasing the net utilization of the gas can lead to a strong enhancement of the profitability of such a process. Reclamation of process chemicals becomes particularly economically viable at a large scale of operation.

### SUMMARY

Therefore a need has arisen for high productivity thin film deposition methods and systems. In accordance with the disclosed subject matter, high productivity thin film deposition methods are provided which substantially reduce or eliminate disadvantages and problems associated with previously developed thin film deposition methods.

This disclosure enables gas recovery and utilization for use in deposition systems and processes. A thin-film semiconductor layer deposition system comprising a deposition reactor, precursor gas feeds, and a gas recovery system is provided.

These and other advantages of the disclosed subject matter, as well as additional novel features, will be apparent from the description provided herein. The intent of this summary is not to be a comprehensive description of the subject matter, but rather to provide a short overview of some of the subject matter's functionality. Other systems, methods, features and advantages here provided will become apparent to one with skill in the art upon examination of the following FIGURES and detailed description. It is intended that all such additional systems, methods, features and advantages included within this description be within the scope of the claims.

### BRIEF DESCRIPTION OF THE DRAWINGS

The features, nature, and advantages of the disclosed subject matter may become more apparent from the detailed description set forth below when taken in conjunction with the drawings in which like reference numerals indicate like features and wherein:

FIG. 1 shows a top view of an embodiment of a wafer susceptor;

FIGS. 2A and 2B show a side view and an enlarged side view, respectively, of an embodiment of a wafer susceptor;

FIG. 3 shows a side view of an embodiment of a reactor with two sets of susceptor plates;

FIG. 4 shows a top view of a batch stack reactor (BSR) embodiment;

FIGS. 5A and 5B show a side view and an enlarged side view, respectively, of an embodiment of a double-sided deposition (DSD) susceptor arrangement;

FIG. 6 shows a top view of an embodiment comprising an array of susceptors;

FIG. 7 shows a side view of an embodiment of a double-sided deposition reactor;

FIGS. 9-12 are schematics depicting embodiments of a deposition reactor and gas capture and recovery system;

FIGS. 13A-B are diagrams illustrating deposition areas for square, pseudo-square, and round substrates;

FIGS. 14A-D are diagrams illustrating embodiments of susceptor arrangements; and

FIGS. 15A-B are diagrams illustrating embodiments of horizontal susceptor arrangements.

### DETAILED DESCRIPTION

Although the present disclosure is described with reference to specific embodiments, such as monocrystalline silicon and depletion-mode epitaxial deposition reactors, one skilled in the art could apply the principles discussed herein to other areas and/or embodiments without undue experimentation.

The present application discloses high-productivity designs and manufacturing methods providing high-productivity, low-cost-of-ownership (low COO) batch wafer epitaxial deposition. The tools provided may utilize gas precursors such as trichlorosilane (TCS) in hydrogen (H₂) for epitaxial silicon deposition or other precursors known in the art. Other low-cost precursors may also be utilized, including but not limited to silicon tetrachloride.

The disclosed subject matter addresses some of the current hurdles to the implementation of high productivity epitaxial deposition systems, mainly by providing leverage through uniformity and gas utilization improvement and reclamation together with teaching an economic path for learning and adjusting complex deposition processes and equipment in order to minimize necessary learning cycles.

Further, the present disclosure references a “wafer” which may be viewed as equivalent to a work piece, semiconductor substrate, substrate, or template upon which the epitaxial deposition occurs. In one embodiment of the present disclosure, the wafer, after epitaxy, may be used repeatedly as a reusable template to grow and release crystalline wafers, preferably thin monocrystalline solar cell substrates formed via vapor phase epitaxy. The use to which the work piece or wafer is put to after epitaxial deposition is beyond the scope of the present disclosure: one of ordinary skill will recognize the myriad uses to which the wafer might be put without departing from the spirit of the present disclosure. Further, this disclosure is written with reference to tools enabling the epitaxial deposition (also called growth) of monocrystalline silicon or other semiconducting materials, including but not limited to any binary and ternary monocrystalline alloys of silicon, germanium, carbon, as well as other compound semiconductors such as gallium arsenide and gallium phosphide.

One novel aspect of the reactor of the present disclosure lies in the arrangement of the wafer susceptors (a susceptor is a material used for its ability to absorb electromagnetic energy and impart that energy, in the form of heat, to the wafers). Although the susceptors may be heated electromagnetically, lamps or resistive heating may also be effective.

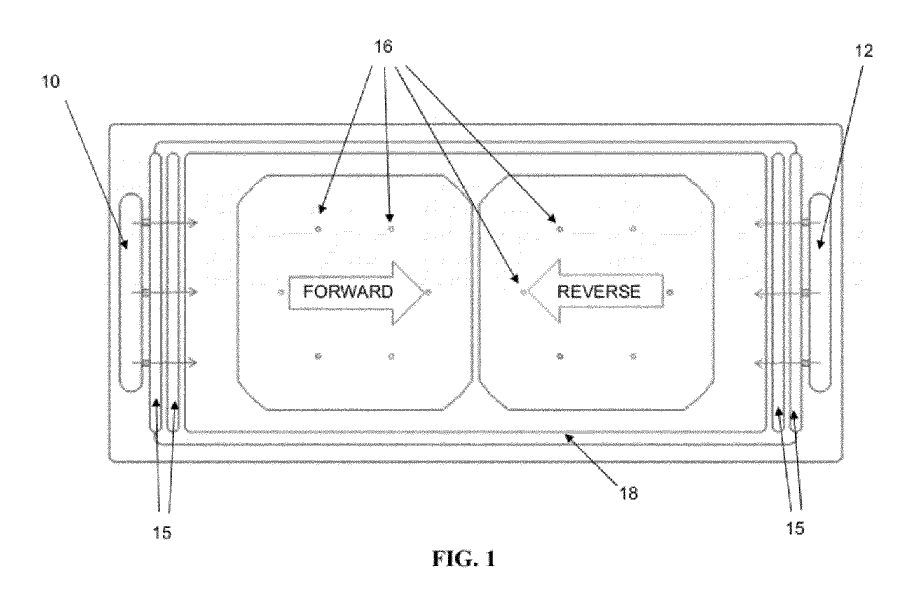

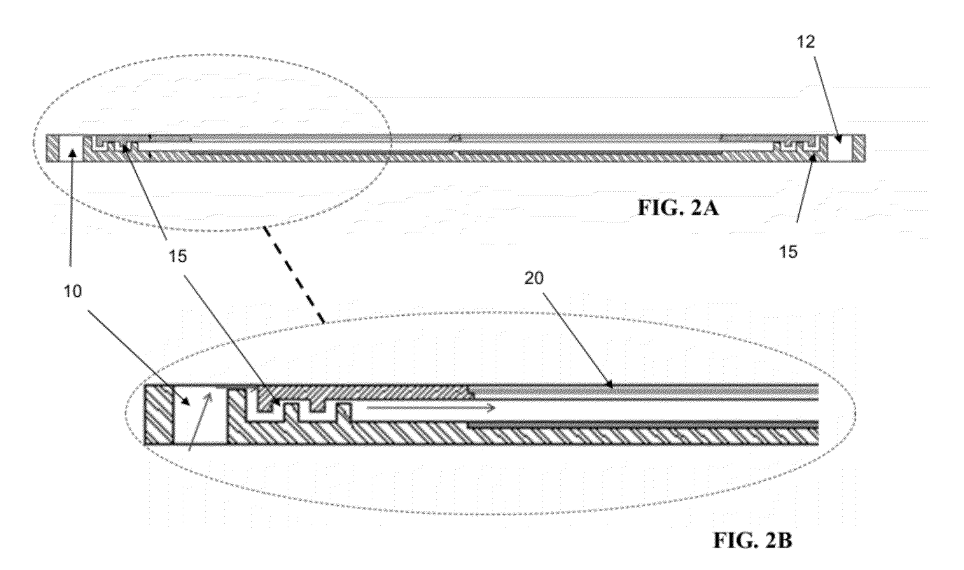

The susceptors of the present disclosure may be stackable, yet they do not rely on stacking for providing the “building blocks” of the overall reactor. The reactors of the present disclosure may or may not be depletion mode reactors (DMRs). “Depletion mode” refers to the depletion or enhanced utilization of chemical along the direction of gas flow. As shown in FIG. 1, that direction may be reversed to even out film thickness from one end to the other. In embodiments where the direction is not reversed, a tendency to deposit more chemicals in the region closest to the source port may be exhibited. In a forward-flow (i.e. left-to-right) mode, port 10 comprises a source port, and port 12 comprises an exhaust port; in a reverse-flow mode, the opposite is true. For that reason, port 10 may be referred to as “source/exhaust port 10,” and port 12 may be referred to as “exhaust/source port 12.” FIGS. 1, 2A, and 2B show different views of the same susceptor arrangement: a top view, a side view, and a detail side view, respectively. As shown in FIGS. 2A and 2B, the design of ports 10 and 12 lends itself to the stackable nature of the wafer susceptors of the present disclosure.

Baffle channels 15 are shown in FIGS. 1, 2A, and 2B. These baffle channels comprise a part of the path through which the TCS or other chemical species flows. Pin holes 16, shown in FIG. 1 only, provide template lift during the epitaxial deposition process.

In these views, template 20 (shown in FIG. 2B) is shown inserted into insert pocket 18 (shown in FIG. 1).

The various dimensions of the reactor shown may be varied by one of ordinary skill without departing from the spirit of the present invention.

In this exemplary embodiment, the thickness of insert pocket 18 is approximately 6 mm, and the length of the whole assembly is approximately 50 cm. The diameter of ports 10 and 12 may be approximately 15 mm.

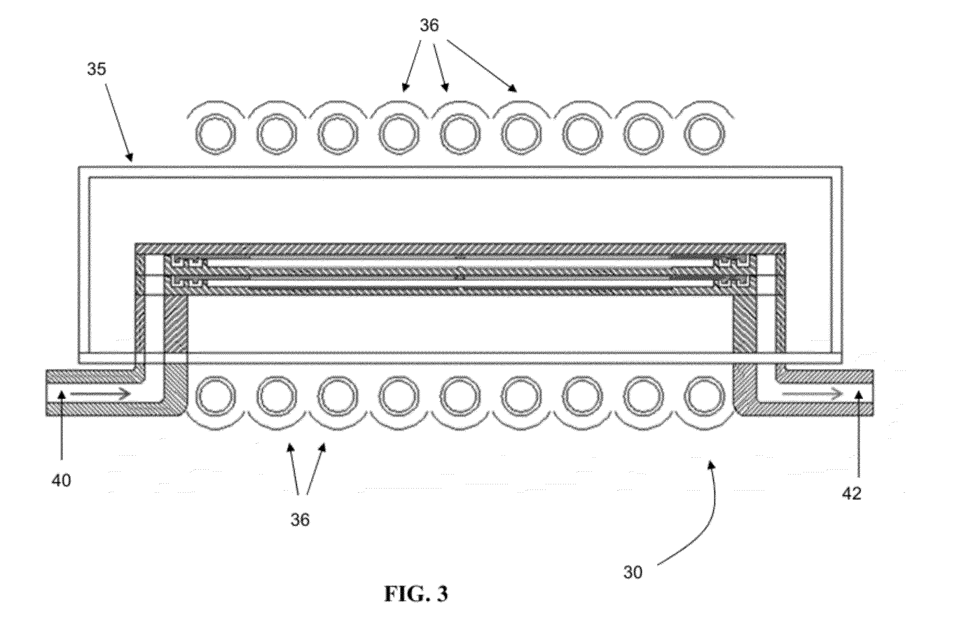

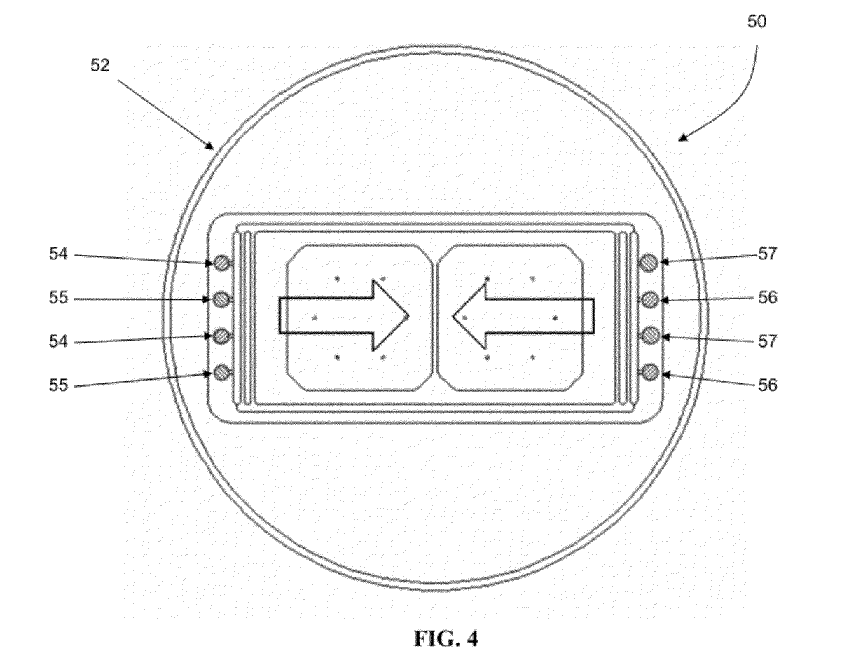

FIG. 3 shows reactor 30, which includes two sets of stacked susceptor plates, similar to the susceptor plates shown in the preceding three FIGURES. The reactor of FIG. 3 is a depletion mode reactor.

Reactor 30 includes source/exhaust port 40 and exhaust/source port 42. The maid body of reactor 30 is housed in quartz muffle 35. As shown, reactor 30 uses lamps 36 for heating the susceptor plates.

During the reaction (or reduction) of TCS with hydrogen gas, hydrochloric acid (HCl gas) is produced. In fact, if the reaction were fed with additional H₂ and allowed to extend over a longer zone or time, the concentration of HCl could continue to rise past the point of reaction inhibition and begin to etch the silicon template. While this is generally a state to be avoided, etching of silicon may be employed to clean the downstream exhaust passages. In effect, by allowing a sufficient level of HCl to build up, one could operate the reactor of the present disclosure in a self-maintaining mode by having the produced HCl gas etch away unwanted deposited silicon.

FIG. 4 shows reactor 50, an embodiment of the present disclosure known as a batch stack reactor (BSR). In this configuration, the susceptor plates are stacked to increase the batch load to, in some embodiments, several hundred wafers in order to enhance the overall reactor productivity. By purging the exterior of the susceptors with H₂ gas, the quartz bell jar is protected from silicon deposition. Most known bell jar reactors are not protected from TCS and require periodic HCl cleaning to remove unwanted deposited silicon. This process may interrupt production, thereby adversely affecting the cost per wafer (i.e. CoO).

Reactor 50 is housed in quartz bell jar 52. In the embodiment shown, reactor 50 includes separate ports for TCS and H₂, although this is not a necessary feature of the present disclosure; in other embodiments, TCS and H₂ may be premixed and fed through the same ports. As shown, H₂ source/exhaust ports 54 and TCS source/exhaust ports 55 are at one end of the reactor; H₂ exhaust/source ports 56 and TCS exhaust/source ports 57 are at the other end. These ports may be differentiated only when acting as source ports. When a given port is being used in an exhaust capacity, it will be exhausting gas that has already been mixed inside the reactor.

TCS reduction with H₂ may result when the gases are mixed at the appropriate temperature. FIG. 4 shows an arrangement of separating the precursors until the point of use at each susceptor. This method may further extend chemical utilization and runtime favoring further improved CoO.

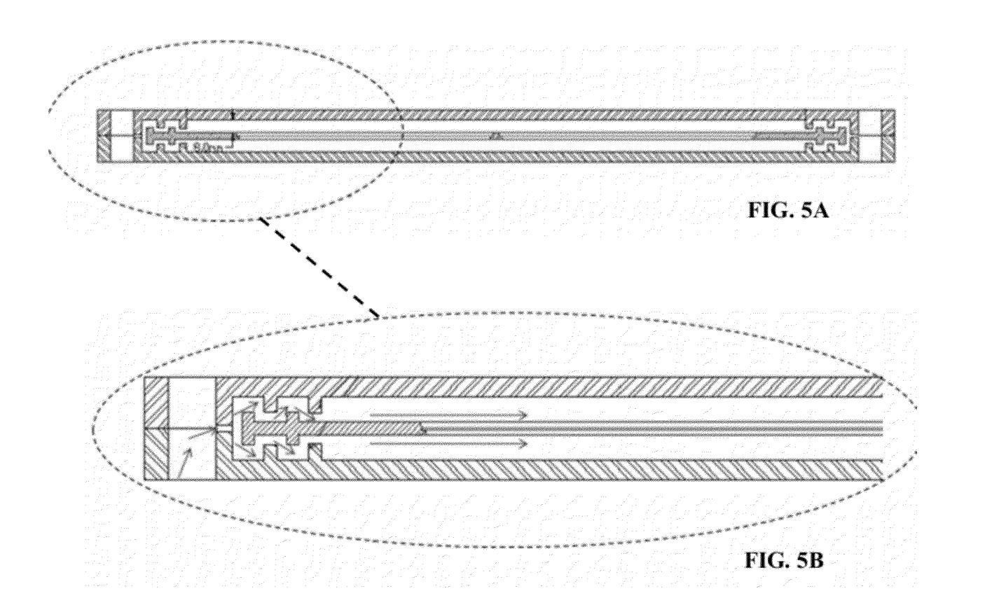

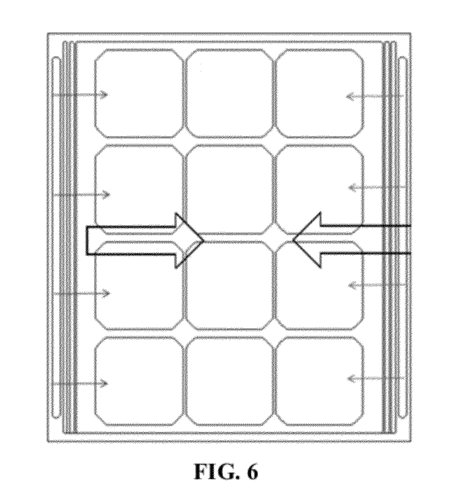

In the arrangement shown in FIGS. 5A and 5B, each template is exposed to process gases on both sides. This feature enables dual side deposition, which has a compounding effect of both increased chemical utilization and lower epi cost per wafer.

The susceptors shown in FIGS. 5A and 5B are generally similar in use to the ones shown in FIGS. 2A and 2B, and may be incorporated into various types of reactor configurations.

The dual sided susceptors may be stackable (as shown in the embodiment of FIG. 3), yet they may also be arranged in a matrix as shown in FIG. 6.

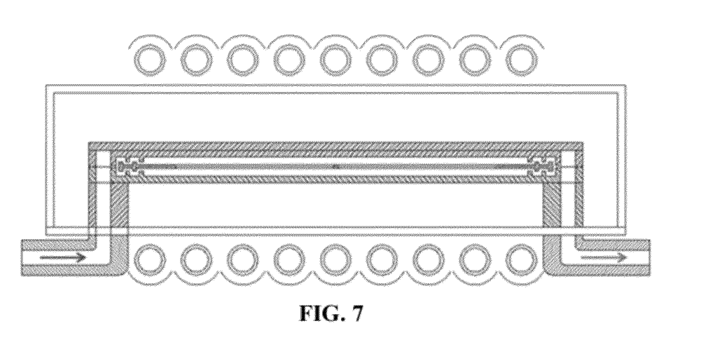

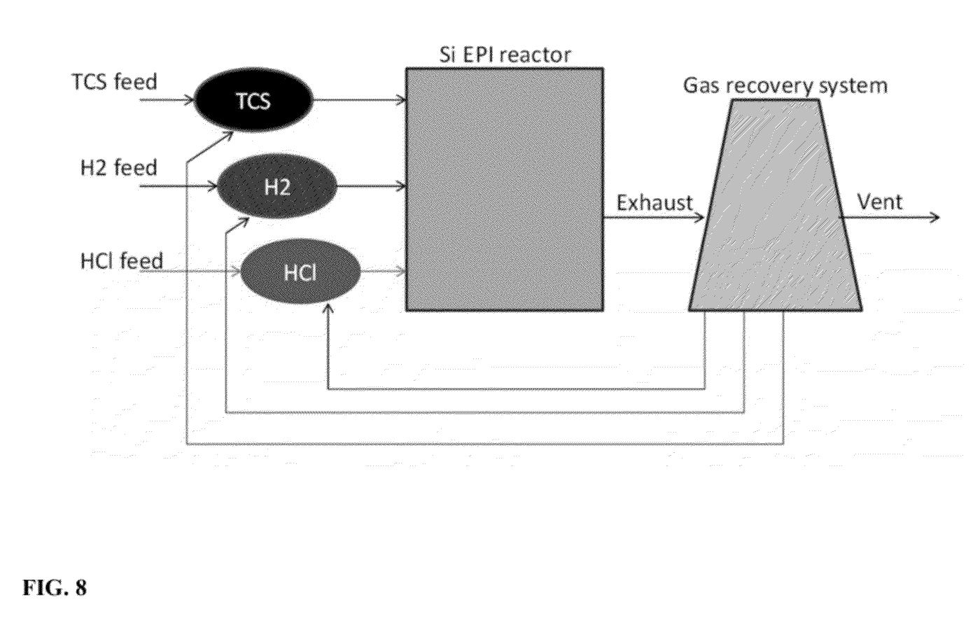

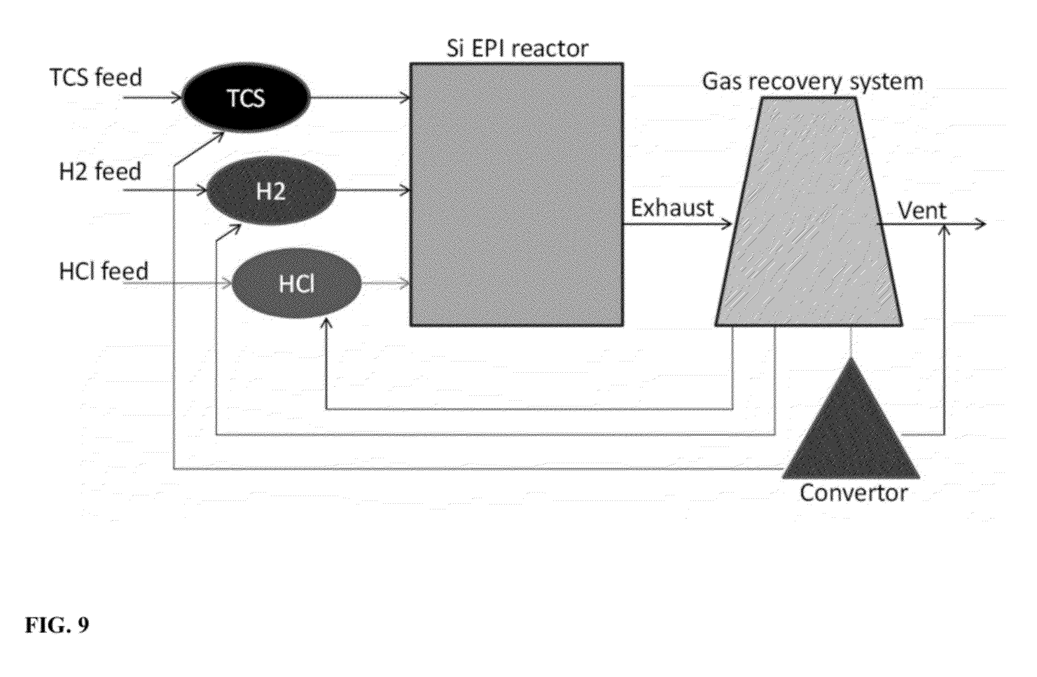

FIG. 7 shows a side view of a depletion mode reactor using the dual sided susceptors of FIGS. 5A and 5B. It is generally similar in structure to the reactor shown in FIG. 3, but with a dual sided susceptor in place of the stacked susceptors.

Those with ordinary skill in the art will recognize that the disclosed embodiments have relevance to a wide variety of areas in addition to those specific examples described above. In particular, any of the disclosed susceptors could be placed into any of the disclosed reactor arrangements without undue experimentation by one of ordinary skill in the art.

In operation, the disclosed subject matter pertains to processing, including but not limited to deposition, of thin film materials in general, but more specifically to deposition of crystalline, including epitaxial monocrystalline silicon films (epi silicon films), for use in manufacturing of high efficiency solar photovoltaic cells as well as other semiconductor microelectronics and optoelectronics applications. Methods and production tools are conceived that allow fabrication of high quality single or dual-sided epi layers in large volumes. The proposed methods and equipment include new means of gas flow depletion compensation across a substrate, processing improvements, heating and channeling the flow of gaseous precursors, means for management of tool power, and ways to suitably precondition the wafer as part of the deposition tool.

The following description and corresponding figures, not limited to the above, relate more directly to the subject matter disclosed in the present application In operation, the disclosed subject matter provide for process flows, unit processes and apparatuses and variations thereof which enable the capture and recovery of high-consumption process gases. These gases may then be used to deposit thin film (or thin foil) layers on a template after which such deposited thin film layers may subsequently be processed to become solar cells. In particular, the capture and recovery methods of this disclosure apply to reclaiming hydrogen and tri-chlorosilane gasses used during silicon epitaxial growth process, as well as reclaiming hydrogenchloride, during susceptor etching process and dopant gases such as diborane and/or phosphine.

In the field of photovoltaics, the disclosed subject matter enables low cost fabrication of thin film and thin foil solar cell semiconductor substrates to be used for solar cell manufacturing by several means, including the capture and recovery of gases that are used for the deposition of thin films or thin foils enables reduction of the overall consumable cost, and therefore, resulting in a reduction of the solar cell manufacturing cost. Thus, the capturing and recovering gases achieves the goal of lowering the overall raw material cost going into the production of thin films.

Additional embodiments include, but are not limited to: the separation of susceptor dry etching and cleaning setups from the more expensive deposition reaction systems to increase the productivity of the deposition reaction systems, resulting in a reduction of the overall solar cell manufacturing cost; the use of square, rectangular, pseudo-square or hexagonal templates which enables optimized active area utilization factors for the deposition gases in the deposition reactors; the use of epitaxial reactor designs that allow for combining high gas utilization with uniform deposition by means of having optimized arrangements of substrate and gas injection geometry which enables both smooth gas flow across several substrates as well as bi-directional gas flow for efficient depletion of the reactant gas species; recovery systems for the gases from a deposition tool which has purification capability that will accept low quality feed gas and provide the required quality of the feed gas to deposition equipment such as Si Epi tool; from an etching process which exhaust gas with HCl, chrolosilane gas and HCl can be recovered through the gas recovery system; and the combination gas recovering system and deposition equipment to provide process flexibility at deposition process without sacrificing gas utilization.

As noted, the reclamation of process chemicals becomes especially economically attractive at a large scale of operation as is the case when a plurality of reaction chambers are connected to one or more recovery systems in a large-scale solar cell manufacturing plant. Such a system may also allow cost savings by reducing scrubber capital and operational expenditure reduction. Typical gases to recover include gasses such as, but are not limited to: Silicon containing gases, such as Silane (SiH4), Dichlorosilane (DCS, SiH2Cl2), Trichlorosilane (TCS, SiHCl3),monochlorosilane (MCS, SiH3Cl) and Silicontetrachloride (STC, SiCl4); Hydrogen (H2); Hydrogenchloride (HCl); and dopant gases such as phosphine (PH3) and diborane (B2H6). The capture and recovery processes may be performed either by co-locating the solar cell manufacturing plant with a TCS-generating plant, or by establishing a dedicated capture and recovery plant.

FIG. 8 is a schematic depicting an embodiment of a gas recovery system, a base gas recovery system, in which the deposition reactor (such as a silicon epitaxial deposition reactor or a farm of Si EPI reactors) location, and also likely the solar fabrication operation, is selected to be in close proximity to a chemical factory that produces polysilicon or silicon containing gases (such as trichlorosilane and/or silicon tetrachloride and/or hydrogen) or liquids (see above). This provides a cheap option not requiring the separation of the effluents of the reaction at the solar factory (location of the Si EPI reactor), but rather at the chemical plant. In this case, using pipelines may reduce transportation cost.

In another embodiment, gases may be condensed out or separated out at the solar factory and may either be re-used directly in part or completely, depending on impurity levels obtained after separation.

The proximity to a factory for TCS and/or polysilicon or silicon containing gases or liquids may also reduce the incoming cost, especially for transportation, of these starting materials for the solar factory, and the solar factory may benefit from the chemical infrastructure of the polysilicon/chemical plant.

Having recovery close to the deposition systems also reduces costs associated with exhaust systems and exhaust system maintenance, as well as electricity costs for keeping exhaust lines heated to avoid condensation in undesired areas.

FIG. 9 is a schematic depicting an embodiment of a gas recovery system with a convertor. As illustrated in FIG. 9, the recovery system may involve some convertors to generate feed gas using separated gas source (STC, DCS, HCl and H2). Herein, the term convertor means a reactor which can convert by-products in exhaust gas stream to feed gas. With Silicon Epi, exhaust gas for a TCS feeding reactor consists of STC, DCS, MCS and/or Silane with HCl (slipped TCS and H2). Utilizing this feature the recovery system may maximize TCS recovery.

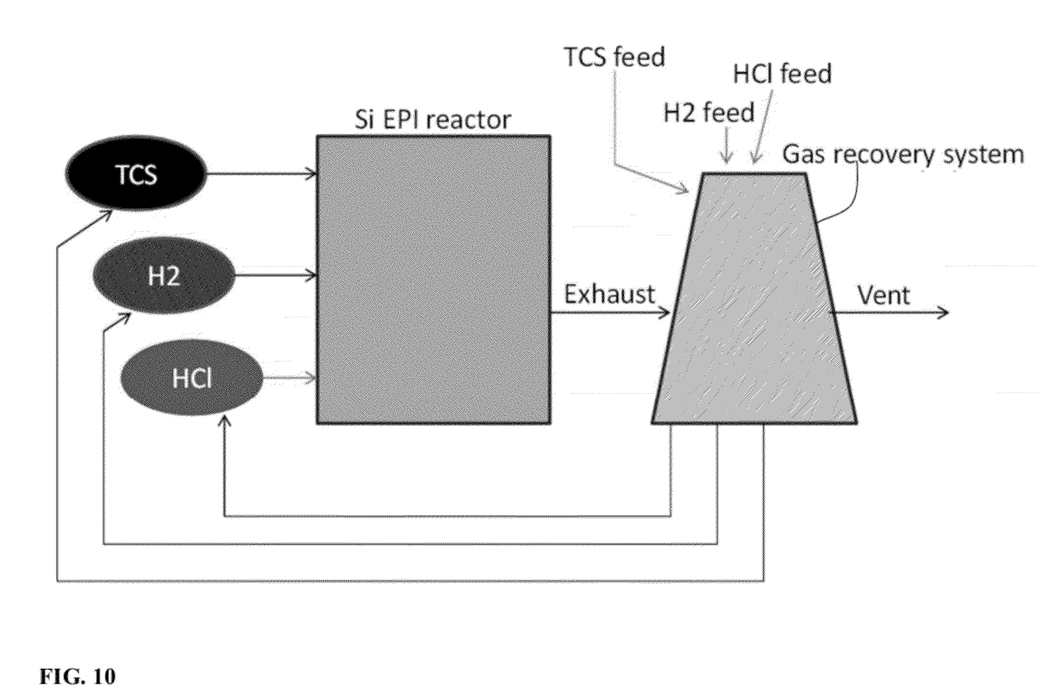

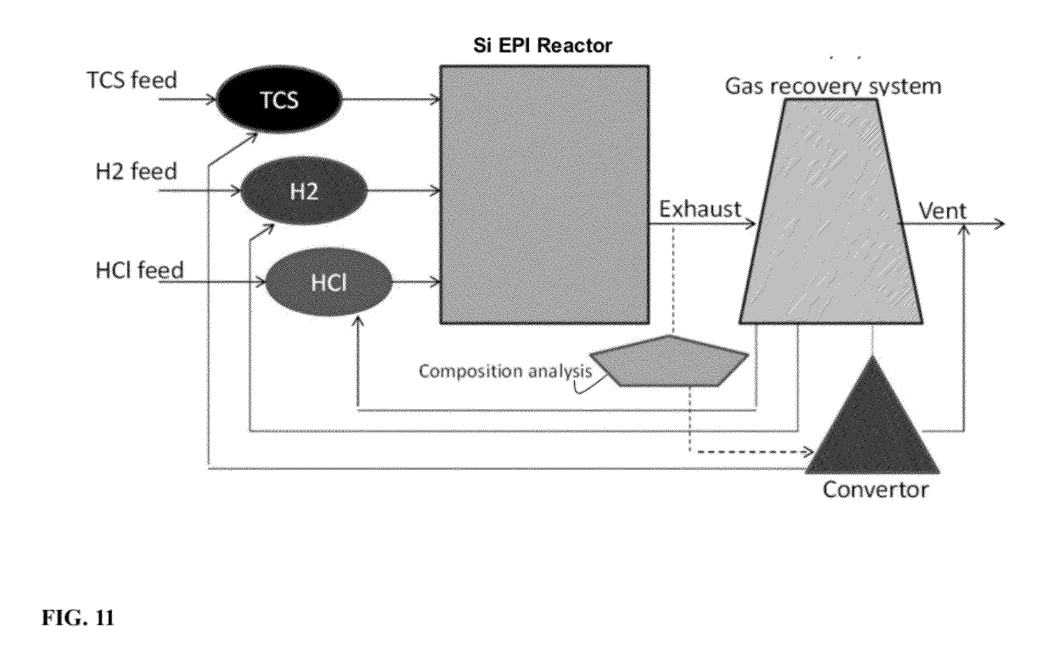

FIG. 10 is a schematic depicting an embodiment of a gas recovery and purification system with low quality feed gas. As can be seen in FIG. 10, low cost low quality feed gas (such as TCS) can be introduced in to the gas recovery system before being sent to the reactor. Due to the reaction and recovery system design, the recovery system has gas purification capability and gas purification may be performed at the same time as reaction—which may further reduce costs.

FIG. 11 is a schematic depicting an embodiment of a process tunable gas recovery system utilizing a gas composition analysis tool. As illustrated in FIG. 11, a recovery system may be operated as a part of deposition reactor. The process condition is sensitive to the TCS flow, feed gas composition, temperature. The resultant gas composition reflects the difference in deposition reaction. Analyzing the gas composition at the exhaust gas stream provide recovery system operating parameter changes to optimize TCS recovery and film quality at the same time. This technique may also minimize operating cost—for example, even with a low TCS conversion rate at the reactor, the gas can be recovered through recovery system and/or reactor in the recovery system.

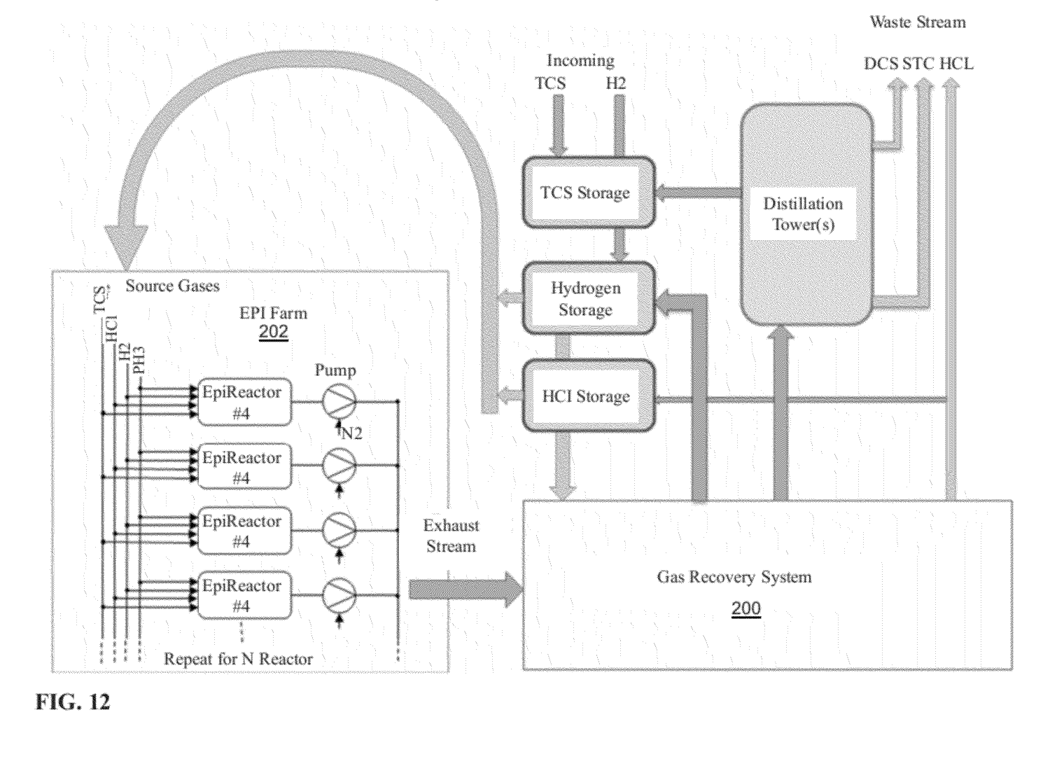

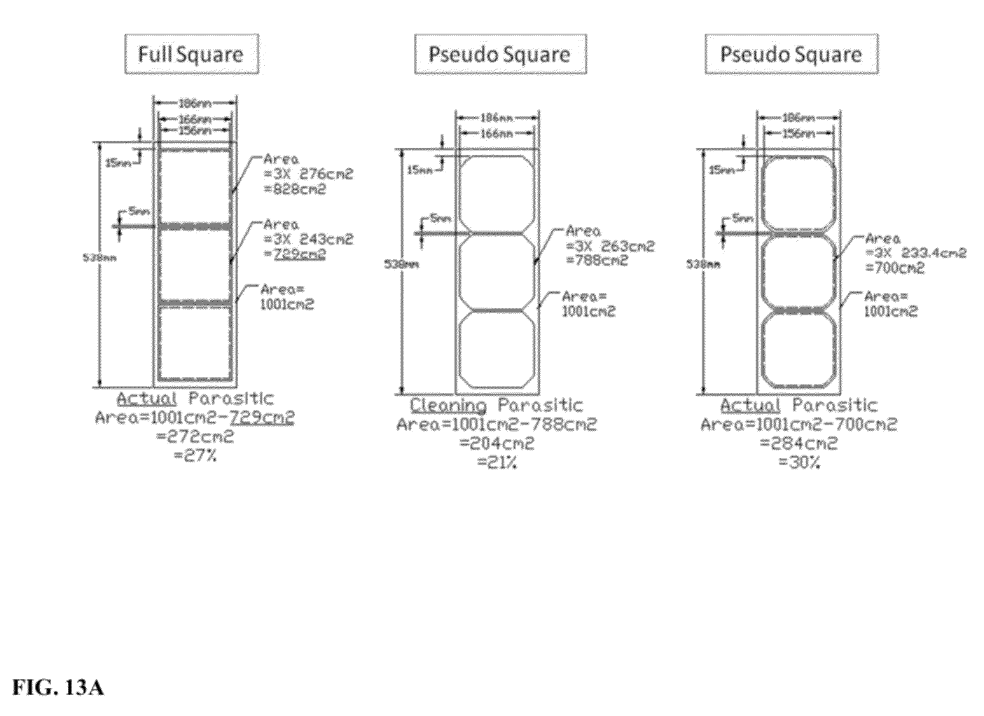

FIG. 12 is a schematic depicting an embodiment of gas recovery system 200 operating in conjunction with a plurality of deposition reactors (such as silicon epitaxial deposition reactors) referred to as EPI Farm 202.

For illustrative purposes, the described embodiments use TCS as the fundamental silicon containing deposition gas in an epitaxial reactor arrangement, however, other embodiments and other deposition gasses may be readily derived by those skilled in the art.

Further, disclosed embodiments may encompass or utilize one, all, or any combination of the following deposition system and process improvements including: A deposition system capable of depositing thin layers of semiconductor on templates which, by further processing, are fabricated into solar cells by releasing said deposited and further processed thin film. A deposition system capable of depositing thin layers of semiconductor on substrates which, by further processing, are fabricated into solar cells. An in-situ or ex-situ etching setup within the same chamber or separate chamber capturing HCl, chlorine or other soluble gases capable of etching Si. A capture and recovery system which collects the volatile byproducts and unreacted reactants of the reaction—in particular, the unreacted reactants of interest include hydrogen, hydrogen chloride, chlorine, and trichlorosilane. A recovery system which separates the volatile byproducts and unreacted reactants of the reaction converting DCS (Dichlorosilane), MCS (Monochlorosilane) or STC (Tetrachlorosilane) to TCS (Trichlorosilane), either by sequential condensation, refrigeration, distillation, thermal or pressure swing adsorption or other suitable means. A recovery system which collects exhaust gas from multiple Si EPi chambers. A storage or transport system for the separated systems. A storage system for unseparated volatile byproducts and unreacted reactants. A reclaim facility or polysilicon feedstock facility which can make use of the collected chemicals. An analysis system to detect purity levels of the captured chemicals. An optimal separation and filtration system for chemicals. A controlled mixing or other delivery system for feeding said separated chemicals back into the process line. An optimal in-situ or ex-situ gas composition analysis system, preferably in-situ in the exhaust stream.

In yet another aspect of the disclosed subject matter, the deposition location may be separated from the susceptor etching location in a deposition reactor arrangement. When a fabrication facility has a plurality of epitaxial or other deposition reactors, there is typically a need to clean susceptors in order to remove accumulated deposited film on the susceptor. The susceptor in a silicon epitaxial deposition reactor is made of silicon carbide coated graphite material, or, may also consist of components of quartz, silica, solid SiC or diamond coated graphite.

One method for cleaning susceptors on a lower cost basis is to run the clean as an ex-situ clean by transporting susceptors from the comparatively expensive epitaxial deposition reactor to a comparatively less expensive batch dry (thermal) etching and cleaning reactor using a halogen-containing ambient. Typical etching chemistries for such processes may be Hydrogen chloride (HCl) or chlorine (Cl2) and the dry etching/cleaning may be performed simply using a thermal etching/cleaning process to selectively remove the deposited silicon material from the susceptor with minimal etching of the silicon carbide coating layer. Other halogen-containing etch gases may be used instead of chlorine (for instance, bromine containing gases). Since etching processes with chlorine (or other halogen) chemistry are carried out at a lower temperature than those using hydrogen chloride, there is potential for a cost benefit using chlorine etching both in terms of reactor hardware as well as in terms of energy usage for the process. Separating the etching reactor from the deposition reactor also enables optimized productivity for the comparatively expensive deposition reactor.

In yet another aspect of the disclosed subject matter, template form embodiments are described for use in deposition systems and methods. The ratio of active area that receives desired value-adding deposition resulting in useful solar cells versus the total area that receives deposition (the total deposition area also includes undesirable non-value-adding parasitic deposition regions on the susceptor and reactor chamber parts) is yet another parameter affecting the cost of a deposition process or system. The balance between the active area and the total area causes a loss in utilization. It is therefore of importance to minimize this area and maximize the value-adding active area percentage.

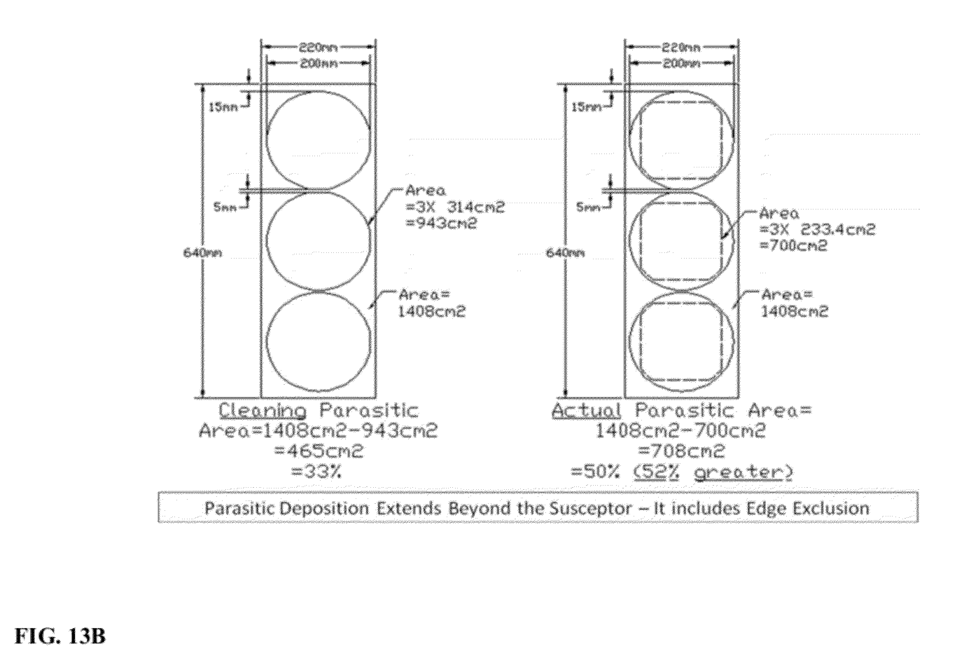

FIG. 13A-B illustrate the productive and parasitic deposition areas for square or pseudo-square substrates versus round substrates and highlights some of the advantages of reducing the area of parasitic deposition when using square or pseudo-square templates to produce square or pseudo-square product substrates versus the use of round templates to produce square or pseudo-square product substrates. FIG. 13A illustrates square and pseudo square substrate embodiments while FIG. 13B illustrates a round substrate embodiment.

In deposition systems, especially those that run in depletion mode (i.e., with the reactants being continually utilized and consumed along the deposition path and along the gas flow), meaning that the reactant in the gas phase gets depleted as it flows across the reaction zone, it is often desirable that the substrates on which deposition is desired (in practice which will be reusable templates) are arranged in a palletized manner. With such a palletized reactor, it is desirable that the templates are of an essentially rectangular or square shape, at least a pseudo square or pseudo rectangle shape as shown in FIG. 13A, as this allows for the highest packing density in the reactor.

Some benefits of a template shape/form factor arrangement, especially as it pertains to the fabrication of solar cells include: a) a square template lends itself best to the fabrication of a square solar substrate, as the substrate is generated by deposition on and then removed from the template for further processing. In this way, the area of non-active solar cell on the template is minimized, in that way optimizing the on-template deposition utilization.

Furthermore, the arrangement of squares or rectangles allows for the closest possible density on any pallet that serves as a susceptor in the deposition reactor. The inactive zones between the templates can be minimized, especially when compared to, for instance, round arrangements which are a natural shape for a Czochralski grown silicon ingot.

With this square template shape/form factor arrangement, the capital productivity of the deposition system is greatly enhanced. Another potential arrangement of high utilization is that of a hexagonal structure, which includes half cut units of hexagons for better corner utilization. A hexagonal geometry has advantages with respect to silicon ingot utilization; however, a hexagonal, or half hexagonal geometry presents other challenges in a solar fab, none the least with respect to material flow logistics and contact/metallization patterns (and also the need to test and sort half-hexagonal cells besides the full hexagonal cells).

From the fundamental thoughts conveyed through these illustrations, parasitic geometrical ratios for other shapes, such as rectangles or hexagons, may be readily derived.

In yet another aspect of the disclosed subject matter, deposition reactor designs optimized for gas utilization and uniformity are provided. For a deposition reactor it is advantageous for cost purposes to have a high utilization of the deposition gas reactants as gas reactants may comprise a high portion of the wafer processing cost. The utilization is determined by the ratio of the deposited quantity of material on the area of the device versus the amount of gas flown across the reactor or reactor portion. As far as the amount of gas flown, only the elemental contribution of the element(s) to be deposited are counted—for instance, for a trichlorosilane precursor, only the silicon content is counted in the denominator of the ratio that defines the utilization.

To obtain a high utilization it is generally advantageous to substantially deplete the gas that is streamed across the substrate on which is the gas is to be deposited on. The deposition process of the element from the gas phase onto the substrate depletes the gas atmosphere above the substrate(s). Therefore, the concentration of the reactant is lowered (depleted) downstream. However, while such depletion is good for utilization, it can be challenging for obtaining good deposition uniformity.

In a reactor with essentially parallel substrates, the gas flow cross-section is essentially rectangular with a cross-section which is approximately constant over a long range. As a compensation to the gas depletion effect, it may be advantageous to tilt the susceptors slightly towards the source of the gas. In an essentially vertical arrangement of substrates, substrates typically are leaning at a small angle from the vertical direction, in order to prevent substrates from being dislodged from the susceptor. Further, in a depletion mode setup, substrates can be stacked into a plurality of vertical tiers and each substrate is typically tilted at a finite angle against the vertical to prevent the substrate from being dislodged from the susceptor. For a vertically stacked array, this leads to a “Z-shaped” or multi-z shaped susceptor / substrate arrangement with ledges between substrates and is depicted in the diagram of 14A.

In a z-shaped susceptor/substrate arrangement, the non-uniformity caused by the desired depletion mode effect may be compensated by using a bidirectional flow arrangement, where reactant gas is flown for a certain time from top to bottom and for another certain time from bottom to top. This leads to an improved uniformity and utilization; however, this setup requires a more complex gas delivery and exhaust setup than a unidirectional arrangement where gas is always flowing in the same direction during the deposition.

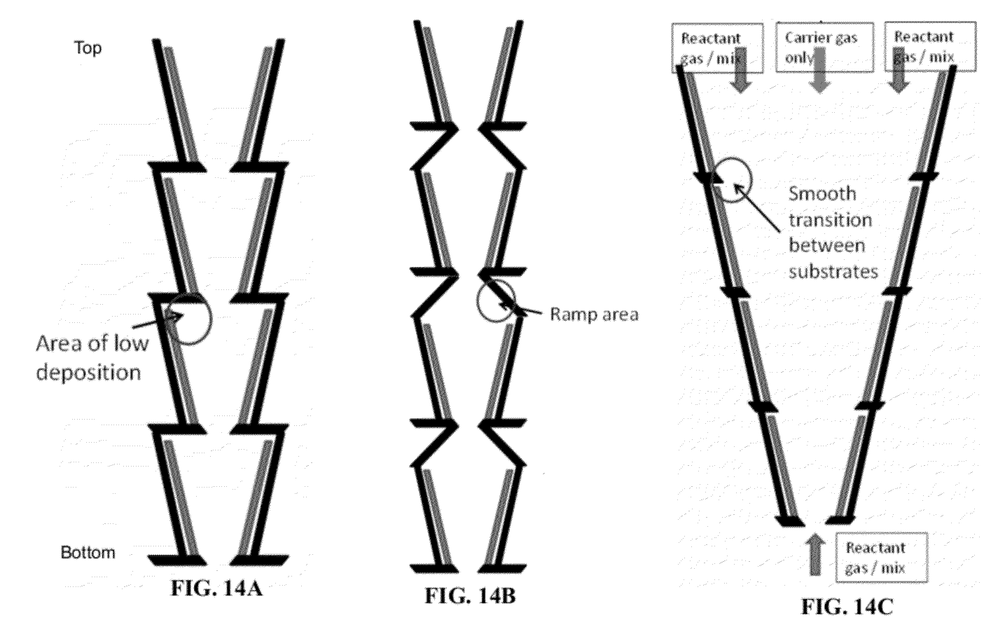

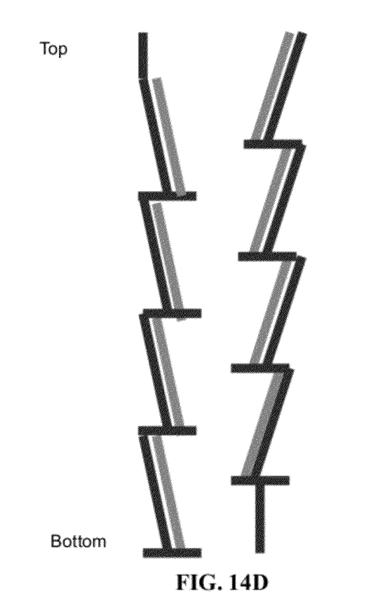

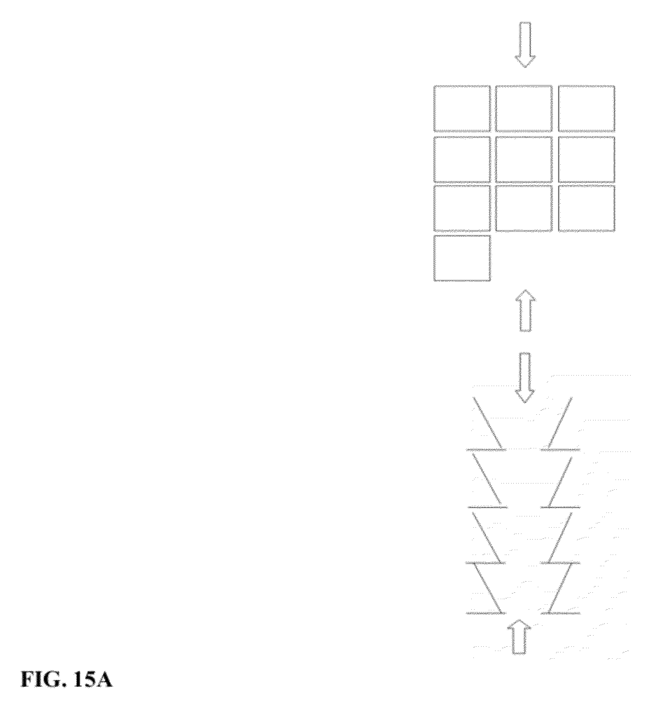

Additionally as can be seen in FIG. 14A, the finite tilt angle of each substrate may then lead to a ledge and subsequent shadowing effects for a gas flowing from top to bottom, whereas for gas flowing from bottom to top, two adversary effects can be observed: first, the depletion is exacerbated by the tilt away from the gas source; second, the ledge can cause a turbulent flow leading to unpredictable, potentially lower quality deposition.

In order to avoid the effect of the ledges between each substrate, several embodiments are herein disclosed.

In a first embodiment, depicted in FIG. 14B, ramps that make the ledge (area of low deposition) more gradual are positioned between the substrates. In such an arrangement, the area vertically between wafers would be slanted such that the reactant gas has sufficient path length to flow close to the surface so as to not have a shading effect underneath the bottom of the top substrate and then at the top of each substrate.

In a second embodiment, depicted in FIG. 14C, a V-shaped susceptor arrangement, which may be referred to herein as a planar z-shaped arrangement, is used thereby providing a smooth transition between the substrates and removing the ledges (areas of low deposition). In a vertical substrate arrangement, substrates are typically facing each other. The described tilt then results essentially in a V-shaped susceptor arrangement, if the substrates tiers are not or only mildly recessed from each other, as can be readily seen in FIG. 14C. For a gas flow from the top to the bottom, or more generally, from the more open side of the V to the more closed side of the V, this V-shaped arrangement allows for a compensation of the depletion of the gas as reactant molecules from the central part of the stream can get closer to the deposition surfaces.

In a third embodiment, depicted in FIG. 14D, a zig zag shaped susceptor arrangement is utilized. When gas flow is fast enough to maximize deposition rate, turbulence tends to occur when local pressure is different from the surrounding area. In these cases, deposition rate around the affected area tends to be different and causes non-uniformity on film thickness. This pressure pocket is usually found in the downstream after a flow obstacle. This zig zag arrangement allows not only all above mentioned Z shape and tilt angle benefits but also minimizes local pressure change. Further, it is important to note that the susceptor arrangement may combine aspects of all the disclosed susceptor arrangement embodiments, such as a combination v-shape and z-shape arrangement having one side or a partial of one side of the reactor with one type of an arrangement different from the remainder of the reactor.

Several effects to be considered for the zig zag arrangement depicted in FIG. 14D as compared to the essentially planar “v-shaped” arrangement depicted in FIG. 14C include the following; however these solutions are applicable to all of the arrangements shown in FIG. 14 and may also be applied readily to other known deposition reactor designs to improve gas utilization and uniformity of deposition.

Close to the gas inlet, the utilization may be lower in the planar v-shaped arrangement depicted in FIG. 14C arrangement as the gas inlet nozzle is further away from the substrate and the same flow now has to cover a larger cross section—thereby flowing less gas per unit time across the surface of the top substrate. A mitigation for this effect is the use of a dual or triple nozzle setup at the open end of the v-shaped arrangement where one set of reactant gas delivery nozzles is arranged close/proximate to one side of the susceptors while the other set of reactant gas delivery nozzles is arranged close/proximate to the other side of the susceptors. A central set of nozzles may be used to flow a carrier gas, such as hydrogen only. This arrangement may then be tuned to keep the reactant gas concentration sufficiently high close to the surface for the substrates in the top tiers.

It is also possible to operate in different regimes of TCS and hydrogen carrier gas flow for the flow from above versus the flow from below. In addition, different partial times of deposition by flow from above versus flow from below may be employed. Further, local zone temperatures and heating powers may be adjusted for optimized gas heating and uniform deposition rate. Heating powers may also be adjusted depending on the gas flow and gas direction to allow for optimized uniformity. As a result, the adverse effect of a ledge may be minimized and good uniformity can be obtained.

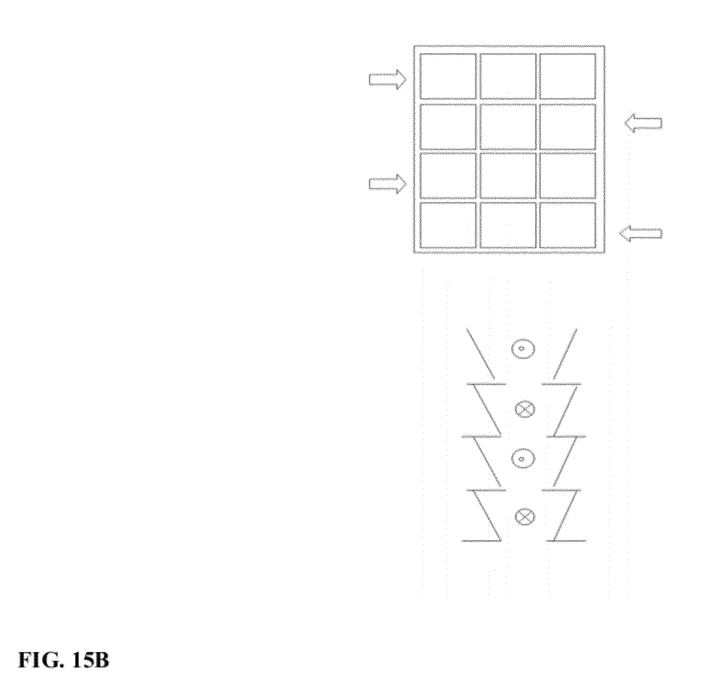

Importantly, is also possible to realize the described arrangement in an essentially horizontal flow arrangement, where the gases are flowing essentially from one side to the other, in a uni- or bi-directional mode, a vertical flow arrangement shown in FIG. 15A and a horizontal flow arrangement shown in FIG. 15B. In such an arrangement, the larger degree of openness of the V-shaped structure may be compensated by suitable arrangement of flow or density of the nozzles of the reactant or carrier gas. Also, in such an arrangement, the ledge structure (“Multi-Z” shaped susceptor of FIG. 14A) does not exhibit the same degree of shading, as the ledges are not arranged vertical to the primary gas flow. Such an arrangement may be combined with an essentially vertical handling of susceptors in and out of the reactor, thereby decoupling the reactor gas feed and gas removal from the susceptor handling.

In operation, the disclosed subject matter provides gas recovery and utilization systems and methods for use in deposition systems and processes.

The foregoing description of the exemplary embodiments is provided to enable any person skilled in the art to make or use the claimed subject matter. Various modifications to these embodiments will be readily apparent to those skilled in the art, and the generic principles defined herein may be applied to other embodiments without the use of the innovative faculty. Thus, the claimed subject matter is not intended to be limited to the embodiments shown herein but is to be accorded the widest scope consistent with the principles and novel features disclosed herein.

It is intended that all such additional systems, methods, features, and advantages that are included within this description be within the scope of the claims.

What is claimed is:

1. A thin-film semiconductor layer deposition system, comprising:
a deposition reactor for depositing a thin-film of semiconductor layer on a plurality of semiconductor substrates;
a plurality of precursor gas feeds attached to said deposition reactor by gas feed lines and providing precursor gasses for the deposition of said thin-film semiconductor layer;
a gas recovery system attached to said deposition reactor by an exhaust line, said exhaust line transporting process gasses from said thin-film semiconductor layer deposition in said deposition reactor to said gas recovery system, said gas recovery system capturing and recovering unreacted precursor gasses for transport to said precursor gas feeds for re-use in said deposition reactor; and
transport lines transporting said captured and recovered gasses to said plurality of precursor gas feeds.

2. The system of claim 1, wherein said gas recovery system further comprises a convertor attached to said gas recovery system for converting useful byproduct gasses of said thin-film semiconductor layer deposition to feed gas.

3. The system of claim 1, wherein said gas recovery system further comprises precursor gas feeds providing precursor gas to said gas recovery system before transport to said deposition reactor.

4. The system of claim 1, further comprising a gas composition analysis tool positioned at said exhaust line and analyzing said process gasses from said thin-film semiconductor layer deposition before transport to said gas recovery system.

5. The system of claim 4, wherein said gas composition analysis tool determines regulation parameters of subsequent gas recovery and purification.

6. The system of claim 1, wherein said deposition reactor comprises a plurality of etching susceptors and a plurality of deposition reaction systems, said plurality of etching susceptors positioned in a separate chamber from deposition reaction systems in said deposition reactor.

7. The system of claim 1, wherein said deposition reactor is a depletion mode reactor for enhanced precursor utilization.

8. The system of claim 7, wherein said semiconductor substrates have a square or pseudo-square shape.

9. The system of claim 7, wherein said plurality of semiconductor substrates are arranged vertically or at a near-vertical orientation in said depletion mode reactor.

10. The system of claim 9, wherein said depletion mode reactor has a z-shaped susceptor arrangement.

11. The system of claim 10, wherein said depletion mode reactor has a z-shaped susceptor arrangement with ramps positioned between said substrates mitigating areas of low deposition.

12. The system of claim 9, wherein said depletion mode reactor has a planar v-shape susceptor arrangement.

13. The system of claim 12, wherein said depletion mode reactor further comprises a multiple nozzle setup at the open end of the v-shaped arrangement providing reactant gas proximate said susceptors.

14. The system of claim 9, wherein said depletion mode reactor has a planar zig zag shaped susceptor arrangement.

15. The system of claim 9, wherein said depletion mode reactor is comprised of a combination of v-shape and z-shaped susceptor arrangement, said z-shaped portion having ramps between susceptors to minimize areas of low material deposition.

16. The system of claim 1, wherein said deposition reactor is an epitaxial silicon deposition reactor.

17. The system of claim 16, wherein said precursor gasses include trichlorosilane.

18. The system of claim 1, wherein the susceptors are etched in-situ after at least one deposition cycle using a chlorine containing gas such as hydrogen chloride or chlorine.

19. The system of claim 1, wherein the susceptors are etched in-situ after at least one deposition cycle using a chlorine containing gas such as hydrogen chloride and byproducts from said etch fed into said gas recovery system.

20. The system of claim 1, wherein the susceptors are etched after at least one deposition cycle using a chlorine containing gas such as hydrogen chloride or chlorine, said etching performed in a separate reactor from said deposition reactor.

21. The system of claim 1, wherein said gas recovery system is combined with a gas purification system.

22. The system of claim 1, wherein said gas recovery system is combined with a gas purification system and fresh gas supplies and fresh liquid precursor supplies are first directed through the recovery or purification system prior to being introduced into the said deposition reactor.

23. A thin-film semiconductor layer deposition system, comprising:
an epitaxial silicon deposition reactor for depositing a thin-film silicon layer on a plurality of silicon substrates;
a plurality of precursor gas feeds attached to said deposition reactor by gas feed lines, said precursor gas feeds providing a silicon containing precursor gas such as silane, dichlorosilane, trichlorosilane or silicon tetrachloride, hydrogen, and hydrogen chloride for the deposition of said thin-film silicon layer;
a gas recovery system attached to said epitaxial silicon deposition reactor by an exhaust line, said exhaust line transporting process gasses from said thin-film silicon layer deposition in said epitaxial silicon deposition reactor to said gas recovery system, said gas recovery system capturing and recovering unreacted precursor gasses for transport to said precursor gas feeds for re-use in said deposition reactor; and
transport lines transporting said captured and recovered gasses to said plurality of precursor gas feeds.

24. The system of claim 23, wherein said thin-film silicon layer is a thin-film monocrystalline silicon layer.

25. The system of claim 23, wherein said deposition reactor is a depletion mode reactor.

26. The system of claim 23, wherein said plurality of semiconductor substrates are arranged vertically in said depletion mode reactor in a planar v-shaped arrangement.

27. The system of claim 23, wherein said plurality of semiconductor substrates are arranged vertically in said depletion mode reactor in a zig zag arrangement.

28. The system of claim 23, wherein a susceptor handling substrates into and out of the reactor is essentially vertical and gas flow is kept essentially horizontal from side to side with the option of changing flow direction.

29. A high-productivity batch epitaxial silicon deposition system, comprising:
a deposition reactor, comprising a plurality of substantially similar batch deposition chambers, for depositing a thin crystalline silicon layer in the thickness range of 1 micron to 100 micron on a plurality of crystalline silicon substrates;
a plurality of precursor gas feeds attached to said deposition reactor by gas feed lines and providing precursor gasses for the deposition of said crystalline silicon layer;
a gas recovery system attached to said deposition reactor by an exhaust line, said exhaust line transporting process gasses from said deposition reactor to said gas recovery system, said gas recovery system capturing and recovering unreacted precursor gases for transport to said precursor gas feeds for re-use in said deposition reactor; and
transport lines transporting said captured and recovered gasses to said plurality of precursor gas feeds.
